(19) United States
(12) Patent Application Publication
(10) Pub. No.: US 2023/0261638 A1
(43) Pub. Date: Aug. 17, 2023

(54) ACOUSTIC WAVE DEVICE

(71) Applicant: Murata Manufacturing Co., Ltd., Nagaokakyo-shi (JP)

(72) Inventors: Katsuya DAIMON, Nagaokakyo-shi (JP); Tetsuya KIMURA, Nagaokakyo-shi (JP)

(21) Appl. No.: 18/136,372

(22) Filed: Apr. 19, 2023

Related U.S. Application Data
(63) Continuation of application No. PCT/JP2021/046509, filed on Dec. 16, 2021.

(30) Foreign Application Priority Data
Dec. 22, 2020 (JP) 2020-212493

(51) Int. Cl. H03H 9/25; H03H 9/02; H03H 9/145; H10N 30/85

(52) U.S. Cl. CPC H03H 9/25; H03H 9/02574; H03H 9/14541; H03H 9/02559; H10N 30/85; H03H 9/02637

(57) ABSTRACT

An acoustic wave device includes a high acoustic velocity structure, a low acoustic velocity layer on the high acoustic velocity structure, a piezoelectric layer directly or indirectly on the low acoustic velocity layer, and an electrode on the piezoelectric layer. The low acoustic velocity layer is made of a dielectric material having a lower Young's modulus than silicon oxide, or includes the dielectric material as a main component.

### CROSS REFERENCE TO RELATED APPLICATIONS

This application claims the benefit of priority to Japanese Patent Application No. 2020-212493 filed on Dec. 22, 2020 and is a Continuation Application of PCT Application No. PCT/JP2021/046509 filed on Dec. 16, 2021. The entire contents of each application are hereby incorporated herein by reference.

### BACKGROUND OF THE INVENTION

### 1. Field of the Invention

The present invention relates to an acoustic wave device including a low acoustic velocity layer and a piezoelectric layer on a high acoustic velocity structure.

### 2. Description of the Related Art

In the related art, an acoustic wave device includes an IDT electrode on a composite substrate having a piezoelectric layer. For example, an acoustic wave device disclosed in Japanese Unexamined Patent Application Publication No. 2015-073331 includes a low acoustic velocity layer made of silicon oxide and a piezoelectric layer made of LiTaO₃ on a high acoustic velocity substrate made of a high acoustic velocity material. An IDT electrode is disposed on the piezoelectric layer. This structure enables effective confinement of acoustic waves in the piezoelectric layer to increase the Q value.

Acoustic wave resonators used for bandpass filters or other devices may need to have a wide fractional bandwidth. It has been, however, difficult to sufficiently increase the fractional bandwidth of acoustic wave devices known in the related art.

### SUMMARY OF THE INVENTION

Preferred embodiments of the present invention provide acoustic wave devices each with a wide fractional bandwidth.

An acoustic wave device according to a preferred embodiment of the present invention includes a high acoustic velocity structure, a low acoustic velocity layer on the high acoustic velocity structure, a piezoelectric layer directly or indirectly on the low acoustic velocity layer, and an electrode on the piezoelectric layer, wherein the low acoustic velocity layer includes a dielectric material having a lower Young's modulus than silicon oxide, or includes the dielectric material as a main component.

Preferred embodiments of the present invention provide acoustic wave devices each with a wide fractional bandwidth.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a front cross-sectional view of a main portion of an acoustic wave device according to a first preferred embodiment of the present invention.

FIG. 2 is a schematic plan view of an electrode structure of the acoustic wave device according to the first preferred embodiment of the present invention.

FIG. 3 illustrates impedance-frequency characteristics of acoustic wave devices of Example 1 of a preferred embodiment of the present invention and Comparative Example 1 used as acoustic wave resonators.

FIG. 4 illustrates impedance-frequency characteristics of acoustic wave devices of Example 2 of a preferred embodiment of the present invention and Comparative Example 2 used as acoustic wave resonators.

FIG. 5 illustrates the relationship between the fractional bandwidth and the materials of a low acoustic velocity layer in an acoustic wave device including a LiTaO₃ film as a piezoelectric layer.

FIG. 6 illustrates the relationship between the fractional bandwidth and the materials of a low acoustic velocity layer in an acoustic wave device including a LiNbO₃ film as a piezoelectric layer.

FIG. 7 is a front cross-sectional view of a main portion of an acoustic wave device according to a second preferred embodiment of the present invention.

### DETAILED DESCRIPTION OF THE PREFERRED EMBODIMENTS

The present invention will be clarified below by describing preferred embodiments of the present invention with reference to the drawings.

The preferred embodiments in this description are illustrative only, and partial replacements or combinations of configurations can be made between different preferred embodiments.

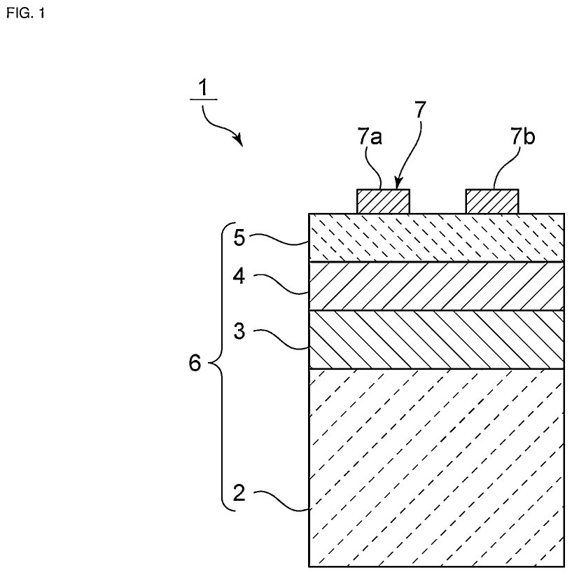

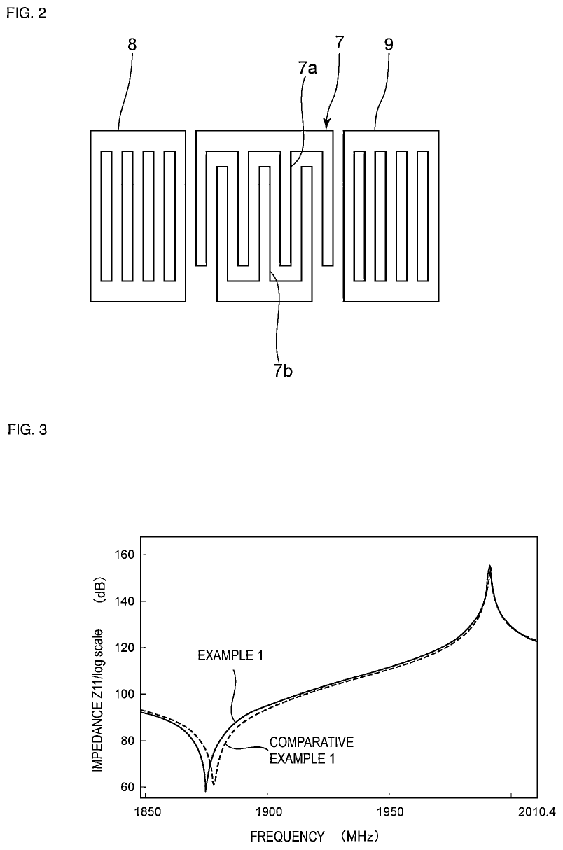

FIG. 1 is a front cross-sectional view of a main portion of an acoustic wave device according to a first preferred embodiment of the present invention. FIG. 2 is a schematic plan view of the electrode structure of the acoustic wave device.

An acoustic wave device 1 includes an IDT electrode 7 on a piezoelectric composite substrate 6.

The IDT electrode 7 includes first electrode fingers 7a and second electrode fingers 7b. The first electrode fingers 7a are interdigitated with the second electrode fingers 7b.

The acoustic wave device 1 is, for example, an acoustic wave resonator. Referring to FIG. 2, reflectors 8 and 9 are disposed on both sides of the IDT electrode 7 in the acoustic wave propagation direction.

The IDT electrode 7 and the reflectors 8 and 9 can be made of an appropriate metal or alloy. The IDT electrode 7 and the reflectors 8 and 9 may each be a multilayer body including two or more metal films.

In the piezoelectric composite substrate 6, a high acoustic velocity member 3, a low acoustic velocity layer 4, and a piezoelectric layer 5 are stacked on a support substrate 2. In the present preferred embodiment, the support substrate 2 is made of, for example, Si. The support substrate 2 may be made of other appropriate dielectrics or semiconductors. The high acoustic velocity member 3 is made of a high acoustic velocity material. The high acoustic velocity material refers to a material in which the acoustic velocity of bulk waves propagating is higher than the acoustic velocity of acoustic waves propagating in the piezoelectric layer 5. Examples of the high acoustic velocity material include aluminum oxide, silicon carbide, silicon nitride, silicon oxynitride, silicon, sapphire, lithium tantalate, lithium niobate, crystal, alumina, zirconia, cordierite, mullite, steatite, forsterite, magnesia, a DLC (diamond-like carbon) film, and diamond, a medium including the above material as a main component, and a medium including a mixture of the above materials as a main component. In the present preferred embodiment, the high acoustic velocity member 3 is made of, for example, silicon nitride (SiN).

The low acoustic velocity layer 4 is made of a low acoustic velocity material in which the acoustic velocity of bulk waves propagating is lower than the acoustic velocity of bulk waves propagating in the piezoelectric layer 5. In addition, the low acoustic velocity layer 4 is made of a dielectric material having a lower Young's modulus than silicon oxide. The dielectric material is not limited, but may be one material selected from the group consisting of aluminum titanate, boron nitride, carbon-containing silicon oxide, and nitrogen-containing silicon carbide. In the present preferred embodiment, the low acoustic velocity layer 4 is made of, for example, aluminum titanate (AlTiO₄).

The Young's modulus of AlTiO₄ is about 13 GPa. The Young's modulus of silicon oxide is about 73 GPa.

For example, the piezoelectric layer 5 is made of a piezoelectric single crystal, and lithium tantalate (LiTaO₃) is used as the piezoelectric single crystal. Lithium niobate may be used. The piezoelectric layer 5 may be indirectly stacked on the low acoustic velocity layer 4.

The piezoelectric composite substrate 6 having the multilayer structure described above enables effective confinement of acoustic waves in the piezoelectric layer 5. This structure can increase the Q value. In addition, the low acoustic velocity layer 4 made of a dielectric material having a lower Young's modulus than silicon oxide can effectively increase the fractional bandwidth as will be apparent from Experimental Examples described below.

The fractional bandwidth in acoustic wave resonators is represented by (fa−fr)/fr, where fr is a resonant frequency, and fa is an anti-resonant frequency.

Next, the resonance characteristics of Examples 1 to 4 will be described to show that the fractional bandwidth of the acoustic wave device 1 can be increased as described above.

### Example 1

An acoustic wave device having the following structure was produced as Example 1 of a preferred embodiment of the present invention.

The support substrate 2 was made of Si with a (111) plane orientation and a third Euler angle of about 73°. The high acoustic velocity member 3 was a SiN film with a thickness of about 300 nm. The low acoustic velocity layer 4 was made of AlTiO₄ with a Young's modulus of about 13 GPa and had a film thickness of about 400 nm.

The piezoelectric layer 5 was a 35° Y-cut X-propagating LiTaO₃ film with a thickness of about 300 nm.

The IDT electrode 7 was a multilayer body including Ti/AlCu/Ti. The film thickness of Ti/AlCu/Ti was about 12 nm/about 100 nm/about 4 nm from the top surface away from the piezoelectric layer 5. The number of pairs of the electrode fingers of the IDT electrode 7 was 100, the intersecting width was about 40 μm, and the wavelength λ determined by the electrode finger pitch was about 2 μm. The intersecting width is a dimension of the region in which adjacent first and second electrode fingers 7a and 7b overlap each other as viewed in the acoustic wave propagation direction, wherein the dimension is along the direction in which the first and second electrode fingers 7a and 7b extend.

For comparison, an acoustic wave device of Comparative Example 1 was prepared in the same or similar manner as in Example 1, except that a silicon oxide film with a thickness of about 300 nm was used as the low acoustic velocity layer 4.

FIG. 3 illustrates the resonance characteristics of the acoustic wave devices of Example 1 and Comparative Example 1 used as acoustic wave resonators. FIG. 3 shows that the resonant frequency in Example 1 can be shifted to the low frequency side compared with Comparative Example 1. The acoustic wave device of Example 1 thus has a wide fractional bandwidth.

The reason for this is described below. When the low acoustic velocity layer 4 has a low Young's modulus, there is a large difference in acoustic impedance between the piezoelectric layer 5 and the low acoustic velocity layer 4, so that acoustic waves can be effectively confined in the piezoelectric layer 5 to increase the fractional bandwidth.

### Example 2

Next, an acoustic wave device including the low acoustic velocity layer 4 made of boron nitride BN was produced as Example 2 of a preferred embodiment of the present invention. The Young's modulus of BN was about 10 GPa. The thickness of the low acoustic velocity layer 4 was about 400 nm. The number of pairs of the electrode fingers of the IDT electrode 7 was 100, the intersecting width was about 40 μm, and the wavelength determined by the electrode finger pitch was about 2 μm. Otherwise, the acoustic wave device of Example 2 had the same or similar structure as the acoustic wave device of Example 1. For comparison, an acoustic wave device of Comparative Example 2 was prepared in the same or similar manner as in Example 2, except that a silicon oxide film with a thickness of about 300 nm was used as the low acoustic velocity layer 4.

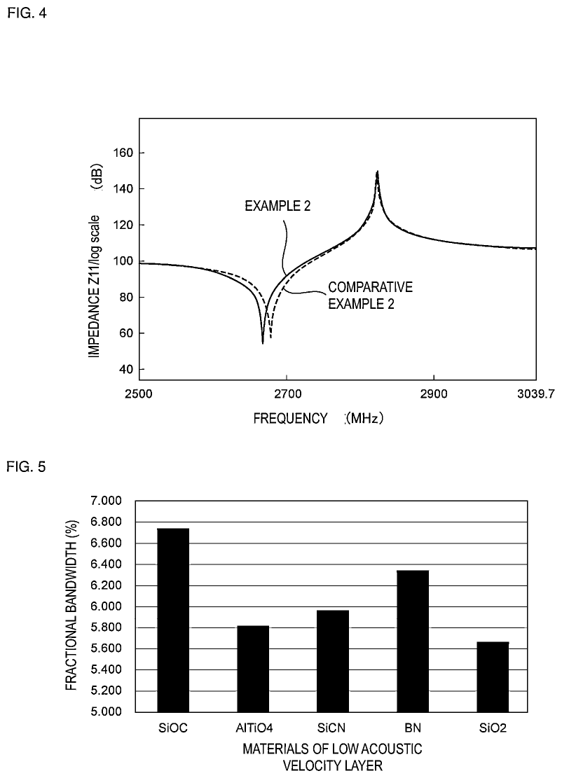

FIG. 4 illustrates the impedance-frequency characteristics of the acoustic wave devices of Example 2 and Comparative Example 2 used as acoustic wave resonators. FIG. 4 shows that the resonant frequency in Example 2 is shifted to the low frequency side to increase the fractional bandwidth, compared with Comparative Example 2.

The results of Example 1 and Example 2 show that the low acoustic velocity layer 4 made of a dielectric material having a lower Young's modulus than silicon oxide may effectively increase the fractional bandwidth of the acoustic wave device according to a preferred embodiment of the present invention. The low acoustic velocity layer 4 may include the dielectric material as a main component. In other words, the low acoustic velocity layer 4 may be a layer including the dielectric material as a main component.

As described above, dielectric materials having a lower Young's modulus than silicon oxide are used as the materials of the low acoustic velocity layer 4 in preferred embodiments of the present invention. Suitable examples of such dielectric materials include carbon-containing silicon oxide SiOC, and nitrogen-containing silicon carbide SiCN, in addition to aluminum titanate AlTiO₄ and boron nitride BN.

### Example 3

In Example 3 of a preferred embodiment of the present invention, an acoustic wave device was produced by stacking the high acoustic velocity member 3 made of silicon nitride (SiN) with a thickness of about 300 nm on the support substrate 2 made of Si and using various dielectric materials with about 200 nm as the low acoustic velocity layer 4.

The piezoelectric layer 5 was a 40° Y-cut X-propagating LiTaO₃ film with a thickness of about 400 nm. The electrode had the same multilayer structure as in Example 1. The wavelength λ determined by the electrode finger pitch of the IDT electrode 7 was about 2 μm, the number of pairs of the electrode fingers was 100, and the intersecting width was about 40 μm.

The dielectric materials were SiOC, AlTiO₄, SiCN, and BN. For comparison, an acoustic wave device including the low acoustic velocity layer 4 made of SiO₂ was also prepared.

The characteristics of these acoustic wave devices used as acoustic wave resonators were evaluated, and the fractional bandwidths of the acoustic wave devices were determined. The results are shown in FIG. 5. FIG. 5 indicates that the fractional bandwidth may be effectively increased by using SiOC, AlTiO₄, SiCN, or BN compared with the case of using SiO₂.

The Young's modulus of SiOC, AlTiO₄, SiCN, BN, and SiO₂ is as described below in Table 1.

TABLE 1

| | Young's modulus |
|---|---|
| SiO₂ | 73 GPa |
| AlTiO₄ | 13 GPa |
| BN | 10 GPa |
| SiOC | 15 GPa |
| SiCN | 40 GPa |

### Example 4

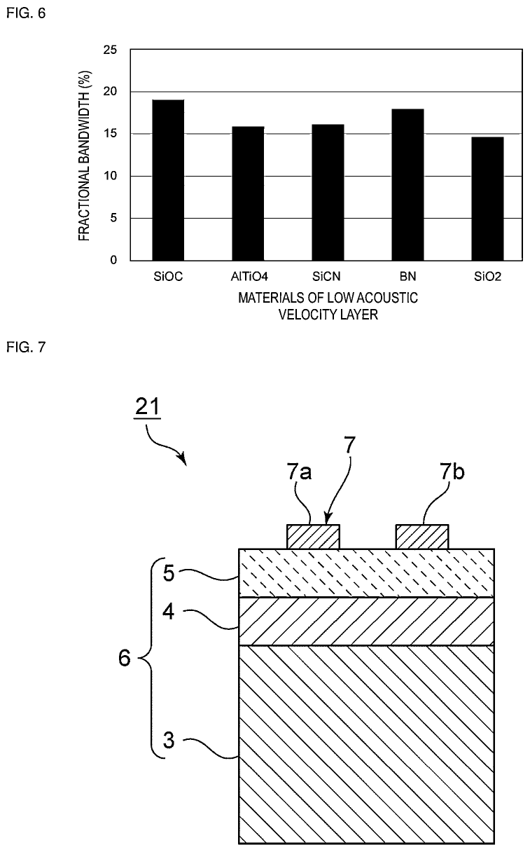

Acoustic wave devices were produced by using various dielectric materials as the low acoustic velocity layer 4 in the same or substantially the same manner as in Example 3, except that a 30° Y-cut X-propagating LiNbO₃ film with a thickness of about 400 nm was used as the piezoelectric layer 5. The resonance characteristics of each acoustic wave device were measured to obtain the fractional bandwidth in the same manner as in Example 3. The results are shown in FIG. 6. FIG. 6 indicates that the fractional bandwidth may be increased by using SiOC, AlTiO₄, SiCN, or BN as the dielectric material of the low acoustic velocity layer 4 compared with the case of using SiO₂. In preferred embodiments of the present invention, the fractional bandwidth can thus be effectively increased even when LiNbO₃ is used as the piezoelectric layer 5.

FIG. 7 is a front cross-sectional view of an acoustic wave device according to a second preferred embodiment of the present invention. FIG. 7 illustrates a main portion of the acoustic wave device.

In an acoustic wave device 21, a high acoustic velocity member 3 is a support substrate made of a high acoustic velocity material. In this case, a high acoustic velocity member made of a material different from that of the support substrate can be omitted. Otherwise, the acoustic wave device 21 is the same or substantially the same as the acoustic wave device 1 illustrated in FIG. 1.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a high acoustic velocity structure;
a low acoustic velocity layer on the high acoustic velocity structure;
a piezoelectric layer directly or indirectly on the low acoustic velocity layer; and
an electrode on the piezoelectric layer; wherein
the low acoustic velocity layer is made of a dielectric material having a lower Young's modulus than silicon oxide, or includes the dielectric material as a main component.

2. The acoustic wave device according to claim 1, wherein the dielectric material is one of aluminum titanate, boron nitride, carbon-containing silicon oxide, and nitrogen-containing silicon carbide.

3. The acoustic wave device according to claim 1, further comprising:
a support substrate; wherein
the high acoustic velocity structure is provided on the support substrate.

4. The acoustic wave device according to claim 1, wherein the high acoustic velocity structure includes a support substrate made of a high acoustic velocity material.

5. The acoustic wave device according to claim 3, wherein the support substrate is a silicon substrate.

6. The acoustic wave device according to claim 1, wherein the piezoelectric layer is made of lithium tantalate or lithium niobate.

7. The acoustic wave device according to claim 1, wherein the electrode includes first electrode fingers and second electrode fingers that are interdigitated with each other.

8. The acoustic wave device according to claim 1, further comprising reflectors on both sides of the electrode.

9. The acoustic wave device according to claim 1, wherein the electrode includes a multilayer body including at least two metal layers.

10. The acoustic wave device according to claim 1, wherein the high acoustic velocity structure includes at least one of aluminum oxide, silicon carbide, silicon nitride, silicon oxynitride, silicon, sapphire, lithium tantalate, lithium niobate, crystal, alumina, zirconia, cordierite, mullite, steatite, forsterite, magnesia, a diamond-like carbon film, or diamond as a main component.

11. The acoustic wave device according to claim 5, wherein the silicon substrate is made of Si with a (111) plane orientation and a third Euler angle of about 73°.

12. The acoustic wave device according to claim 1, wherein the piezoelectric layer is a 35° Y-cut X-propagating LiTaO₃ film with a thickness of about 300 nm.

13. The acoustic wave device according to claim 1, wherein the electrode includes a multilayer body including a first Ti film, an AlCu on the first Ti film, and a second Ti film on the AlCu.

14. The acoustic wave device according to claim 13, wherein
the first Ti film has a thickness of about 12 nm;
the AlCu film has a thickness of about 100 nm; and
the second Ti film has a thickness of about 4 nm.

15. The acoustic wave device according to claim 1, wherein the low acoustic velocity layer is made of boron nitride having a thickness of about 400 nm.

16. The acoustic wave device according to claim 1, wherein the high acoustic velocity structure is made of silicon nitride having a thickness of about 300 nm.

17. The acoustic wave device according to claim 1, wherein the piezoelectric layer is a 40° Y-cut X-propagating LiTaO₃ film with a thickness of about 400 nm.

18. The acoustic wave device according to claim 1, wherein the piezoelectric layer is a 30° Y-cut X-propagating LiNbO₃ film with a thickness of about 400 nm.
